(19) United States
(12) Patent Application Publication
(10) Pub. No.: US 2026/0173923 A1
(43) Pub. Date: Jun. 18, 2026

(54) THROUGH GLASS VIA STRUCTURES INCLUDING AN ORGANIC SEED MATERIAL LAYER FOR INTEGRATED CIRCUIT DEVICE PACKAGES

(71) Applicant: Intel Corporation, Santa Clara, CA (US)

(72) Inventors: Jeremy Ecton, Gilbert, AZ (US); Aleksandar Aleksov, Chandler, AZ (US); Srinivas Pietambaram, Chandler, AZ (US); Brandon Marin, Gilbert, AZ (US); Gang Duan, Chandler, AZ (US)

(73) Assignee: Intel Corporation, Santa Clara, CA (US)

(21) Appl. No.: 18/986,594

(22) Filed: Dec. 18, 2024

(51) Int. Cl. H01L 23/538; H01L 21/48; H01L 23/15; H01L 23/498; H01L 23/64; H01L 25/065

(52) U.S. Cl. CPC H10W 70/65; H10W 44/501; H10W 70/05; H10W 70/611; H10W 70/664; H10W 70/666; H10W 70/685; H10W 70/692; H10W 90/00

(57) ABSTRACT

Integrated circuit (IC) die packages including a glass with conductive features embedded within the glass, such as through-glass vias (TGVs). The embedded features comprise metallization electrolytically plated with an organic seed layer on sidewalls of the glass that may be supplemented with an inorganic seed layer on top or bottom surfaces of the glass. Where the embedded features comprise a coaxial inductor, the metallization includes a non-magnetic metal surrounded by a magnetic metal layer. The organic seed layer has sufficient electrical conductivity for plating the metals, but displays lower parasitic currents during operation of the coaxial inductor. In exemplary embodiments, the organic seed layer has a low elastic (Young's) modulus to accommodate internal stress between the glass and the embedded metallization.

### BACKGROUND

In electronics manufacturing, IC packaging is a stage of semiconductor device fabrication in which an IC that has been monolithically fabricated on a chip (or die) is assembled into a “package” that can protect the IC chip from physical damage and communicatively connect the IC to other packaged IC chips and/or a scaled host component, such as a package substrate, or a printed circuit board. Multiple chips can be co-assembled, for example, into a multi-die package (MCP).

Stiffer package substrate cores, for example of bulk glass, have been explored as low-warpage, high-flatness alternatives to organic resin-based cores. However, a glass substrate has a significantly lower CTE than conventional organic copper-clad cored or coreless substrates. When electrically conductive features, such as through-glass vias (TGVs), are formed within the glass substrate, the glass can be exposed to high stresses associated with the embedded conductive features. These high stresses can potentially result in mechanical failures and reduce IC device package yields. These issues are particularly challenging when embedding coaxial inductor structures within a TGV, for example because of the additional need to form magnetic material within the TGV.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods for electroplating metal within through-glass vias (TGVs) by first lining through holes with an organic seed material layer, in accordance with some embodiments;

FIGS. 2 and 3A illustrate cross-sectional views of an IC device package structure evolving to include TGV openings and an inorganic seed material layer as one or more operations in the methods illustrated in FIG. 1 are performed, in accordance with some embodiments;

FIG. 3B illustrates a cross-sectional view of an IC device package including an inorganic seed material layer supplemented with an organic seed material layer within TGV openings as one or more operations in the methods illustrated in FIG. 1 are performed, in accordance with some embodiments;

FIG. 4 illustrates a cross-sectional view of an IC device package following electrolytic plating of one or more metals within TGV openings lined with organic seed material layer, in accordance with some embodiments;

FIG. 5 is a flow diagram of methods for forming an IC device package structure including a coaxial inductor by depositing both inorganic and organic seed material layers over a glass substrate and electroplating a magnetic metal and a non-magnetic metal within through-glass vias (TGVs), in accordance with some embodiments;

FIGS. 6, 7, 8, 9, 10, 11, 12, and 13 illustrate cross-sectional views of an IC device package structure evolving to include a coaxial inductor structure embedded within a glass substrate as one or more operations in the methods illustrated in FIG. 5 are performed, in accordance with some embodiments;

FIGS. 14 and 15 illustrate cross-sectional views of an IC device package structure evolving to include multiple IC dies interconnected by an electrical routing structure built up on a side of a glass core that includes through-glass coaxial inductor structures as one or more operations in the methods illustrated in FIG. 5 are performed, in accordance with some embodiments;

FIG. 16 illustrates a system including the IC device package structure illustrated in FIG. 15 attached to a host component with solder features, in accordance with some embodiments;

FIG. 17 illustrates a mobile computing platform and a data server machine employing device package structures comprising through-glass coaxial inductor structures, in accordance with some embodiments; and

FIG. 18 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

Integrated circuit (IC) device package structures including a glass perform with embedded metallization, such as conductive through-glass vias (TGVs), are described herein. An electrical routing structure comprising redistribution layer (RDL) metallization may be built-up on at least one side of the glass and electrically coupled to the metallization embedded within the glass. IC die(s) may be further assembled to the routing structure. In exemplary embodiments, the metallization embedded within the glass is electroplated over an organic seed material layer, which may be absent from metallization extending over a front or back side surface of the glass, and which may be supplemental with an inorganic seed material layer.

As described further below, an organic seed material has sufficient electrical conductivity to support electrolytic plating of one or more metals upon a sidewall of an opening or recess in the glass. The organic seed material may have a low elastic (e.g., Young's) modulus, and advantageously strain to accommodate (i.e., buffer) stress between the glass and electroplated metals. The organic seed material may further have a relatively low electrical conductivity, which may advantageously reduce electrical parasitics during operation of inductor structures that include a magnetic metal electroplated upon the organic seed material within the opening or recess in the glass. Electrolytic deposition(s) dependent upon the organic seed material may be supplemented and/or enhanced with an inorganic seed material formed on a surface(s) of the glass, for example beyond the opening or recess. The inorganic seed material may improve electroplating efficiency and enhance plating rates on the glass backside and/or frontside surface(s) relative to within openings in the glass.

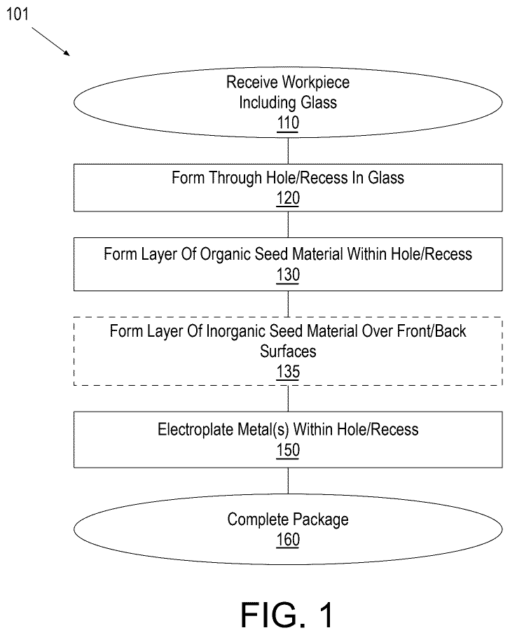

A variety of fabrication methods may be practiced to form IC device package structures having one or more of the features described herein. FIG. 1 illustrates a flow diagram of methods 101 for forming organic and inorganic seed material layers upon a glass preform and electroplating one or more metals over the seed material layers. Methods 101 begin at input 110 where a workpiece including a thickness of glass is received. The workpiece may be prepared upstream of methods 101 and may be in a large panel format, a wafer format, or the like. In addition to the glass, the workpiece received at input 110 may comprise one or more surface cladding materials upon which electrical routing structures may be formed.

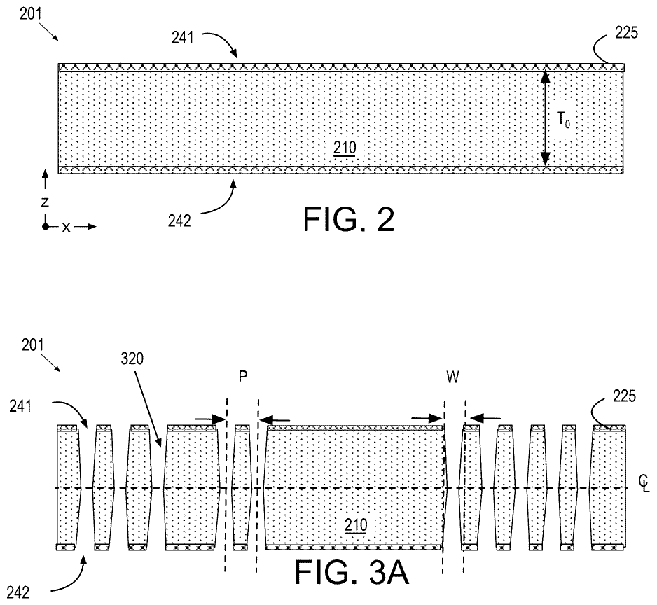

FIG. 2 is a cross-sectional view of an exemplary substrate core 201 including glass 210. IC device package structures may be advantageously fabricated upon glass 210 as flatness and/or thickness control for a preform of glass may be superior to that of starting substrates based on organic materials (e.g., epoxy), and costs can be significantly lower than for monocrystalline materials (e.g., silicon). Glass 210 may also be stiffer than conventional core materials, such as a copper-clad laminate (CCL). Glass 210 is a solid bulk material layer that may have been previously formed into any shape in plan view (e.g., x-y plane) suitable for a packaging workpiece, such as rectangular. Glass 210 has a thickness T₀ that may vary with implementation, for example to limit warpage while remaining thin enough to permit the formation of through vias at a pitch as small as is enabled by the surface flatness of glass 210. In exemplary embodiments, thickness T₀ is advantageously 50 μm to 2000 μm. Organic adhesives and/or other organic material may be absent from glass 210. Glass 210 is advantageously a bulk material of substantially homogeneous composition in contrast to a composite material that may merely comprise glass fillers (particles) and/or glass fibers in a binder (e.g., epoxy). Although glass 210 is substantially amorphous in some embodiments, glass 210 may also have other morphology or microstructure, such as polycrystalline (e.g., nanocrystalline). Glass 210 may therefore be a rectangular prism volume distinguished from, for example, “prepreg,” which typically includes glass fibers having a diameter in the range of 5-20 μm embedded in a resinous organic material, such as an epoxy.

Glass 210 may include a material comprising silicon and oxygen. Glass 210 is advantageously predominantly silicon and oxygen. In some embodiments, glass 210 comprises at least 23 percent silicon and at least 26 percent oxygen, by weight (i.e., wt. %). Glass 210 may further include one or more additives, such as, Aluminum, Boron, Magnesium, Calcium, Barium, Tin, Sodium, Potassium, Strontium, Phosphorus, Zirconium, Lithium, Titanium, or Zinc. In glass 210, the weight percentage of silicon is at least 0.5% (e.g., between about 0.5% and 50%), and may be between about 1% and 48%. For example, if glass 210 is specifically fused silica, the weight percentage of silicon may be about 47%. In some embodiments where glass 210 comprises at least 23 wt. % Si, glass 210 comprises at least 26 wt. % O. Additives within glass 210 may form suboxides (A₂O) monoxides (AO), binary oxides (AO₂), ternary oxides (ABO₃), and mixtures thereof. For example, glass 210 may comprise AlOₓ (e.g., Al₂O₃), BOₓ (e.g., B₂O₃), MgOₓ (e.g., MgO), CaOₓ (e.g., CaO), SrOₓ (e.g., SrO), BaOₓ (e.g., BaO), SnOₓ (e.g., SnO₂), NaOₓ (e.g., Na₂O), KOₓ (e.g., K₂O), POₓ(e.g., P₂O₃), ZrOₓ (e.g., ZrO₂), LiOₓ (e.g., Li₂O), TiOₓ (e.g., TiO₂), or ZnOₓ (e.g., ZnO₂). In some specific examples glass 210 further comprises at least 5 wt. % Al. Depending on chemical composition, glass 210 may therefore be referred to as silica, fused silica, aluminosilicate, soda-lime glass, soda-lime silica, borofloat glass, lead borate glass, borosilicate, or alumino-borosilicate, for example.

As further depicted in FIG. 2, one or more material layers 225 may clad either or both of the front-side glass surface 241 or back-side glass surface 242 so that glass 210 is a bulk or core layer of a multi-layered substrate. In some embodiments, material layer 225 is an inorganic material. In some examples, the inorganic material is a metal seed layer having sufficient electrical conductivity at some predetermined material layer thickness to support an electroplating process. In some embodiments, the metal seed layer is predominantly copper (Cu), and may be essentially pure Cu with only a trace amount (e.g., <1 wt. %) of impurities. The metal seed layer may also be of varying composition and/or a stack of two or more sublayers. For example, a metal seed layer may comprise around 50 nm of primarily Ti in contact with glass 210 and around 100 nm of primarily Cu over the Ti. In other embodiments, material layer 225 is an alternative inorganic dielectric material such as silicon nitride (SiNₓ) or silicon oxynitride (SiOₓN_{y}). In other embodiments, material layer 225 may be a silicon layer (polycrystalline or monocrystalline). In still other embodiments, material layer 225 may instead be an organic material layer, such as polymer dielectric material. Hence, while glass 210 is advantageously substantially free of organic materials (e.g., no adhesives, etc.), an IC die package workpiece may further include organic materials within a substrate stack that includes glass 210.

Returning to FIG. 1, methods 101 continue at block 120 where a feature (e.g., recess and/or through hole) is formed in the glass preform. The feature may be fabricated with any process known to be suitable for bulk glass. In some embodiments, block 120 comprises laser ablation, a glass etch process (laser-assisted, or otherwise), or any other technique known to be suitable for forming a feature (e.g., hole) through a thickness of the glass received at input 110 at a desired diameter and feature pitch. For some embodiments, features are photolithographically defined in a mask material at block 120 and the glass is then etched according to the mask features. For embodiments where the workpiece includes one or more cladding layers over the glass preform, the features formed in the glass preform may also be formed in the cladding layers, either with the same process employed to pattern the glass or with a separate process.

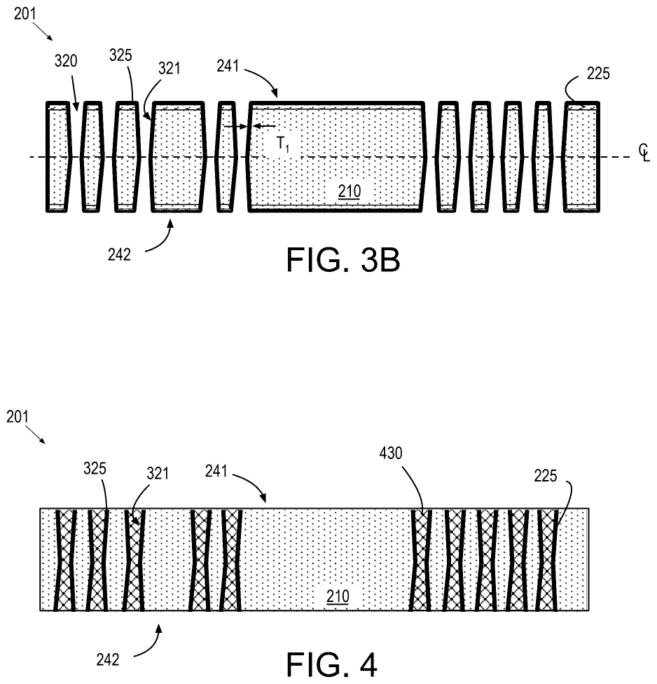

FIG. 3A illustrates an exemplary embodiment indicative of a substantially symmetrical two-sided opening formation process resulting in openings 320 that are substantially symmetric about a longitudinal z-axis (demarked in dashed line), but with a tapered (e.g., x dimension) lateral width W that is largest at each of glass surface 241 and glass surface 242. Openings 320 have a smallest lateral width W proximal to one-half of thickness T₀ or a centerline plane of glass 210. The largest width W may vary with implementation. However, in some examples the largest width W is 100 μm, or less, and advantageously 50 μm, or less. Accordingly, the aspect ratio (T₀: largest width W) of openings 320 may also vary with an exemplary aspect ratio range being 10-20:1.

In some embodiments where glass 210 has a thickness T₀ of at least 500 μm, openings 320 have a minimum lateral pitch P that is 200 μm, or less, and advantageously 100 μm, or less. Although the symmetrical taper illustrated in FIG. 3A is indicative of a two-sided through hole formation process, single-sided asymmetrical though-hole embodiments are also possible. While through-holes are illustrated in FIG. 3, blind holes or recesses that do not pass entirely through thickness T₀ may also be fabricated into one or more of glass surface 241 or glass surface 242. Openings 320 (or blind holes) may have any shape within a plan view (x-y) plane, such as substantially circular, rectangular, or any other polygon. The plan view shape of a through hole, or blind hole, may also vary over thickness T₀.

As further shown in FIG. 3A, openings 320 extend through front-side and back-side surface cladding material layer 225. Hence, following through hole patterning, material layer 225 is present on glass surface 241 or glass surface 242, but absent from a glass sidewall surface within openings 320.

Returning to FIG. 1, methods 101 continue at block 130 where one or more electrically conductive material layers are formed over the glass preform. These material layer(s) are to facilitate electroplating one or more metals within the hole or recess at block 150 and are therefore referred to as (plating) seed material layers. At block 130, an organic seed material layer is formed at least over a sidewall surface of an opening or recess in the glass preform. In some embodiments, the organic seed material layer is formed or retained over only the sidewall surface. In other embodiments, the organic seed material layer is formed and retained over the front and/or back side surfaces of the glass preform as well as over a sidewall surface of openings in the glass.

For embodiments where the front and back side surfaces of the glass preform are not already clad in an inorganic seed material layer, an inorganic seed material may be formed on the front and/or back side surfaces of the glass at block 135. The inorganic seed material layer may supplement the organic seed material layer formed on a sidewall of the feature at block 130, for example to reduce total electrical resistance of the composite seed layer or otherwise improve electroplating performance at block 150. Block 135 is demarked with dashed line to emphasize that the addition of inorganic seed material on the front and/or back side surfaces of the glass is optional. For example, where the glass preform is already clad with an inorganic seed material, block 135 need not be practiced. In another example where the organic seed material is deposited over the sidewall surface and also over the front and/or back side surfaces of the glass preform, block 135 need not be practiced where the organic seed material of sufficiently low electrical resistance for adequate performance of the plating at block 150.

An organic seed material layer may be formed at block 130 according to any technique suitable for forming material on a sidewall of the feature patterned in the glass preform. In some embodiments, a polymer precursor fluid is applied with a process such as slit-coating, spin-coating, spray-coating, dip-coating, or ink-jet printing. In other embodiments, a self-assembly techniques (e.g., driven by surface-charges) may be practiced to form an organic material layer. The polymer precursor may be dried and/or cured to evaporate solvent from the fluid and form an organic polymer seed material with suitable mechanical properties. In some examples, the cure may include heating the workpiece to temperatures of between 200 C. and 500 C. for 10 minutes, or more.

FIG. 3B illustrates an exemplary embodiment where an organic seed material layer 325 has been formed over substrate core 201. As shown, organic material layer 325 is over front-side glass surface 241, back-side glass surface 242 and a sidewall glass surface 321 within openings 320. Since organic seed material is over surface cladding material layer 225, for embodiments where cladding material layer 225 is an inorganic seed layer (e.g., Cu), a multi-layered inorganic/organic material stack is present over front and back side glass surfaces 241, 242 while a single layer of organic material is on sidewall 321.

In exemplary embodiments, organic seed material layer 325 is an electrically conductive polymer. Although electrical conductivity of organic seed material layer 325 may vary with implementation, in some embodiments the material electrical conductivity is at least 100 S/cm and may be 1000 S/cm, or more. However, in some advantageous embodiments where cladding material layer 225 is a Cu seed layer, organic seed material layer 325 has an electrical conductivity below that of cladding material layer 225. As further described below, embodiments of organic seed material layer 325 with lower electrical conductivity may improve the performance of certain devices, such as coaxial inductor structures. Hence, electrical conductivity of organic seed material layer 325 may be optimized between plating performance and operational performance of a resulting device structure. Although in some instances electrical conductivity of organic seed material 325 may be directly measured, references herein to electrical conductivity are also applicable for bulk materials having substantially the same chemical composition and microstructure as the organic seed material 325. Hence, even if electrical conductivity of organic seed material layer 325 is not directly measurable in-situ, a material of substantially the same composition and microstructure may be formed to some greater thickness more amenable to electrical measurement. Absent evidence to the contrary, the electrical conductivity of such a bulk thickness is presumed to be closely matched with that of a thin film of substantially the same composition and microstructure.

In some further embodiments, organic seed material layer 325 is of a material having an elastic modulus less than 110 GPa. The inventors have found that materials with an elastic modulus significantly above this threshold (e.g., 120 GPa) may not accommodate sufficient internal stress and, when deposited within hole or recess in glass, a less compliant material(s) may suffer delamination. Some embodiments of organic seed material layer 325 may therefore have an elastic modulus advantageously below 100 GPa, and more advantageously below 90 GPa. References herein to elastic modulus are also applicable for bulk materials having substantially the same chemical composition and microstructure as the thin film. Hence, even if elastic modulus of organic seed material layer 325 is not directly measurable, a material of substantially the same composition and microstructure may be formed to some greater thickness more amenable to modulus measurement. Absent evidence to the contrary, the modulus associated with such a bulk thickness is presumed to be closely matched with that of the thin film of substantially the same composition and microstructure.

In further embodiments, organic seed material layer 325 is of a material having a relatively low (linear) coefficient of thermal expansion (e.g., <20 ppm/K), which is compatible with the CTE of silica glass (e.g., 4-9 ppm/K). In some exemplary embodiments, organic seed material layer 325 may advantageously have a CTE in the range of 3-20 ppm/K, and more specifically in the range 5-12 ppm/K. Although in some instances the CTE may be directly measured for organic seed material layer 325, references to CTE are also applicable for bulk materials having substantially the same chemical composition and microstructure as organic seed material layer 325. Hence, even if CTE of organic seed material layer 325 is not directly measurable, a material of substantially the same composition and microstructure may be formed to a greater thickness more amenable to CTE measurement. Absent evidence to the contrary, the CTE associated with such a bulk thickness is presumed to be closely matched with that of a thin film of substantially the same composition and microstructure.

The composition of organic seed material layer 325 may vary with deposition technique and may be determined, for example, through one or more of FTIR, Raman spectroscopy, AFM, AFM-IR, TEM, XPS, or X-EDS. Generally, organic seed material layer 325 may include at least one of a trifluoromethyl group, a carbonyl group, a sulfonyl group, or an ester group, which may all be detected by FTIR or XPS, for example.

In some embodiments, organic seed material layer 325 is of a chemical composition known to be suitable as conductive material in organic light emitting diodes (OLEDs), or polymer light-emitting diodes (PLEDs). Generally, such organic polymers comprise primarily carbon chains and may further comprises heterocyclic structures, for example including oxygen and/or sulfur. In some examples, organic seed material layer 325 comprises a dioxy poly(3,4-ethylenedioxythiophene) (PDOT) and a counter ion, such as, poly(styrenesulfonate) (PSS). PDOT: PSS π conjugated polymers are known to be capable of having a wide range of electrical conductivity as a function of the thickness of organic seed material layer 325. In other embodiments, organic seed material layer 325 comprises 3,4-ethylenedioxythiophene (EDOT), Thieno[3,4-c]pyrrole-4,6-dione (TPD)-based conjugated monomers, polypyrrole (PPy), polypyrrole-polystyrene sulfonate (PPy: PSS), polyaniline (PANI), or the like.

As further illustrated in FIG. 3B, organic seed material layer 325 has a sidewall layer thickness T₁ along a direction perpendicular to the sidewall 321. Although sidewall layer thicknesses T₁ may vary with implementation, in exemplary embodiments minimum sidewall layer thickness T₁ is at least 500 nm. In some advantageous embodiments, thickness T₁ is 0.5 μm to 5 μm. A greater thickness of organic material layer 325 is advantageous for accommodating stress, for example by straining along thickness T₁. A greater thickness of organic material layer 325 may also improve plating efficiency. However, thickness T₁ may be limited to keep electrical conductivity of organic seed material layer 325 below some predetermined threshold.

In the exemplary embodiments illustrated by FIG. 3B, organic seed material layer 325 is in direct contact with glass 210. However, in alternative embodiments one or more intervening material layers may be between glass 210 and organic seed material layer 325. For example, as described further below, organic seed material layer 325 may be in contact with an intervening liner material layer that may improve adhesion of organic seed material layer 325 and/or serve some other function.

With both an organic seed material layer 325 along a sidewall of glass 210 and an inorganic seed material layer 225 over front/back side surfaces of glass 210, one or more metals are electroplated upon the workpiece at block 150 (FIG. 1). Electroplating may be according to any method known to be suitable for lining and/or substantially filling a recess or opening in an IC die package substrate. Electroplating may be selective, for example limited according to one or more plating masks, or a non-selective (blanket) metal deposition process may be performed. In some embodiments, one or more fill metals (e.g., predominantly copper) may be electroplated upon surfaces of the seed material layers. Rates of metal deposition may vary between inorganic seed material layer 225 and organic seed material layer 325. For example, where inorganic seed material layer 225 has higher electrical conductivity than organic seed material layer 325, the electrodeposition rate may be lower local the organic seed material layer 325 (i.e. within an opening or hole) than over inorganic seed material layer 225. An electroplated metal may have a significantly higher elastic modulus and/or CTE than organic seed material layer 325. Fill metallization of predominantly Cu, for example, can be expected to have an elastic modulus of around 130 GPa and a CTE of 16-17 ppm/K.

FIG. 4 illustrates an example where a fill metal 430 has been plated within opening 320 upon organic seed material layer 325. In this example, metal overburden plated upon surfaces 241 and/or 242 has been completely removed through a planarization process. Alternatively, the workpiece illustrated in FIG. 4 may also be obtained through chemical metal etch processes, with or without incorporating mechanical abrasion. The metal removal process has also removed inorganic seed material layer 225, exposing glass 210 and leaving only conductive TGV structures extending between glass front side surface 241 and glass back side surface 241. Notably, organic seed material layer 325 remains as a permanent feature of the TGV structures.

Returning to FIG. 1, methods 101 end at output 160 where a package is completed, for example with the workpiece being completed as a package substrate that may be further incorporated with an IC die. Any known IC die package substrate processes, such as redistribution layer (RDL) metallization build-up may be performed at output 160 as embodiments are not limited in this respect. Any die attach processes may be further practiced at output 160.

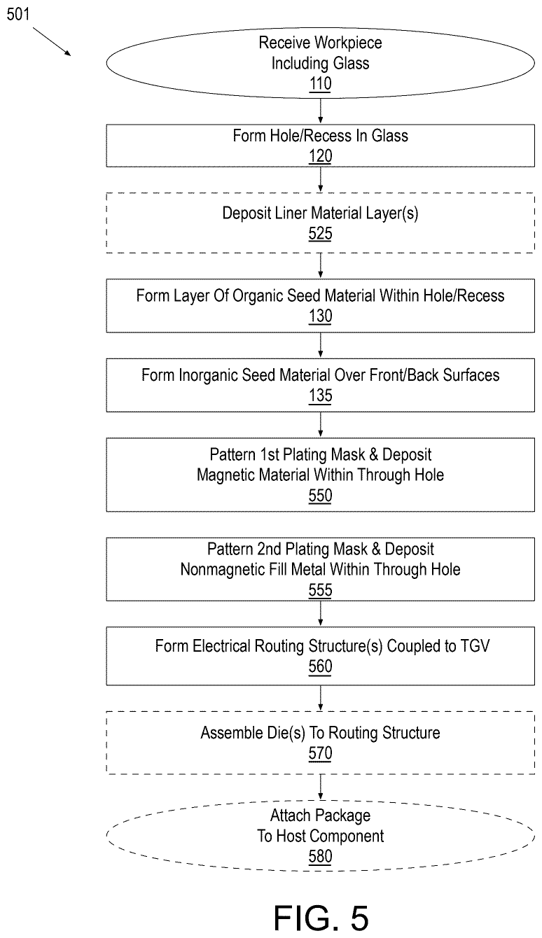

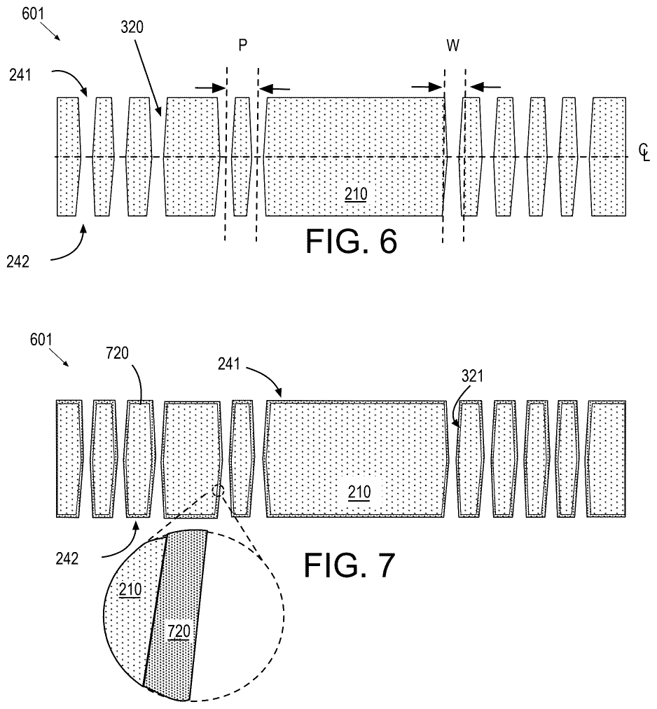

FIG. 5 is a flow diagram of methods 501 for forming an IC device package structure including an embedded coaxial inductor by depositing both inorganic and organic seed material layers over a glass substrate and electroplating both magnetic and non-magnetic metals within a TGV structure. Methods 501 are therefore a subset of embodiments of methods 101. FIG. 6-13 illustrate cross-sectional views of an IC device package structure evolving to include a coaxial inductor structure embedded within a glass substrate as operations in methods 501 (FIG. 5) are performed, in accordance with some exemplary embodiments.

Referring first to FIG. 5, methods 501 begin with input 110 where a workpiece including glass is received. The workpiece received may have any of the properties and/or attributes of the workpiece described above in the context of methods 101 (FIG. 1). Methods 501 (FIG. 5) continue at block 120 where a through hole or recess is formed at block 120. The through hole or recess may be formed according to any of the techniques described above in the context of methods 101 (FIG. 1), for example. FIG. 6 illustrates an exemplary embodiment where substrate core 601 includes a openings 320 through glass 210. In contrast to substrate core 201 (FIG. 3A), substrate core 601 lacks an inorganic seed material on frontside and backside surfaces 241, 242. Substrate core 601 may have any of the other attributes described above in the context of FIG. 3A.

Returning to FIG. 5, methods 501 may optionally include the deposition of one or more liner materials at block 525 (illustrated in dashed line to emphasize the optional nature of block 525). In some embodiments, an inorganic liner material is deposited at block 525. The inorganic liner material may be, for example a dielectric or an intermetallic compound of high electrical resistivity. The inorganic liner may function as an adhesion layer, for example. In other embodiments, an organic liner material is deposited at block 525. In contrast to an organic seed material, an organic liner material formed at block 525 is of high electrical resistivity (i.e., an electrical insulator or non-conductor).

In advantageous embodiments, liner material deposition is with a “dry” process that is capable of forming thin films of material on a sidewall of a feature having a high aspect ratio (e.g., over 10:1). For inorganic material embodiments, block 525 may comprise a deposition process offering high film thickness conformality, such as chemical vapor deposition (CVD) or atomic layer deposition (ALD) although less conformal physical vapor deposition (PVD) techniques may also be practiced. For organic material embodiments, block 525 may also comprise a vapor deposition technique. In one example, an initiated chemical vapor deposition (iCVD) process deposits a polymeric material on sidewalls of openings, for example in direct contact with the inorganic material previously deposited. Generally, in iCVD techniques a monomer is deposited upon a workpiece surface and, an athermally activated initiator radical activates the monomer, initiating a polymerization reaction on the surface. Such techniques provide the opportunity for grafting a polymer directly on the inorganic material previously deposited. It is also possible to leave dangling bonds on the top surface of the organic material, providing bonding sites for a next material layer that could enhance adhesion with the organic material.

FIG. 7 illustrates an example where a liner material layer 720 has been deposited upon substrate core 601. In this example, liner material layer 720 has been deposited over glass surfaces 241, 242 as well as sidewalls 321 of openings 320. Liner material layer 720 is in direct contact with glass 210.

In some inorganic embodiments, liner material layer 720 advantageously comprises only trace levels of carbon below 1.0 wt %, if any. In further embodiments, liner material layer 720 comprises nitrogen. Functional groups comprising nitrogen (e.g., nitrides) can have particularly good adhesion to glass surfaces, reducing the risk of a liner delaminating from glass 210. Nitride functional groups may also promote good adhesion to a subsequently deposited organic material layer. In some embodiments, liner material layer 720 further comprises silicon, and may advantageously be a silicon nitride (SiNₓ) with one example being stoichiometric Si₃N₄. In some embodiments, liner material layer 720 comprises oxygen, either in combination with both silicon and nitrogen (e.g., SiOₓN_{y}) or in the absence of nitrogen (e.g., SiOₓ) where one example is stoichiometric SiO₂. Optionally, one or more metals may also be present in liner material layer 720. Exemplary metals include one or more of Ti (e.g., TiNₓ, TiOₓ, TiOₓN_{y}, TiSiₓ, TiSiₓO_{y}N_{z}), Ta (e.g., TaNₓ, TaOₓ, TaOₓN_{y}, TaSiₓ, TaSiₓO_{y}N_{z}), or W(e.g., WNₓ, WOₓ, WOₓN_{y}, WSiₓ, WSiₓO_{y}N_{z}). Other metals (e.g. com Al, Sn, Sc, In, or Au), and their nitrides, oxides, silicides, or silicates are also possible.

In some organic embodiments, liner material layer 720 is a polymer material with significantly higher carbon content than for inorganic embodiments. In some embodiments, liner material layer 720 is an organic polymer, but is of a different composition than that of an electrically conductive organic seed material. Although the composition of the organic polymer may vary, some examples include Polytetrafluoroethylene (PTFE), Poly(Glycidyl Methacrylate) (PGMA), poly (1,3,5-trimethyl-1,3,5-trivinyl cyclotrisiloxane) (pV3D3), poly (1,3,5,7-tetravinyl-1,3,5, 7-tetramethy|cyclotetrasiloxane) (pV4D4), or poly(1H, 1H, 2H, 2H-perfluorodecyl acrylate (pPFDA). Such materials may be deposited by iCVD with an initiator such as tert-butyl peroxide (TBPO) for PGMA or Perfluoro butane sulfonyl fluoride (PBSF) for PTFE.

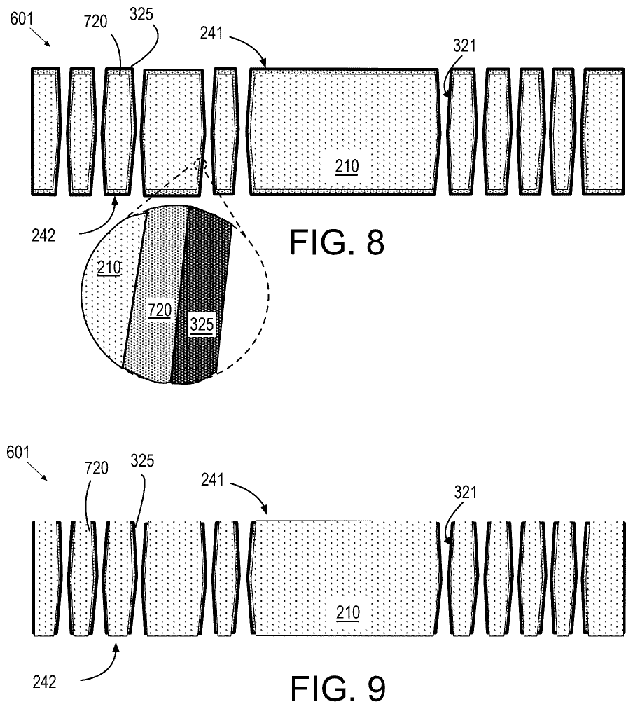

Returning to FIG. 5, methods 501 continue at block 130 where a layer of organic seed material is formed within a hole or recess in glass. Block 130 may comprise any of the processes described above in the context of methods 101 (FIG. 1) to form any of the organic seed material layers described above. In the example illustrated in FIG. 8, substrate core 601 now includes organic seed material layer 325. In this example, organic seed material layer 325 has been deposited over glass surfaces 241, 242 as well as sidewalls 321 of openings 320. For embodiments including liner material layer 720, organic seed material layer 325 is in direct contact with liner material layer 720. For embodiments lacking liner material layer 720, organic seed material layer 325 may instead be in direct contact with glass 210. Seed material layer 325 may have any of the chemical compositions described above and may similarly possess any of the attributes or properties described above.

As further illustrated in FIG. 9, organic seed material layer 325 may be selectively removed from frontside glass surface 241 and/or backside glass surface 242. Alternatively, organic seed material layer 325 may be selectively formed only within openings 320 to arrive at the same structure illustrated in FIG. 9. Selective removal may be through a surface planarization process, for example. Such a process may also remove any underlying liner material layer, exposing glass 210. In alternative embodiments, an etchant or solvent of organic seed material layer 325 may be applied to frontside surface 241 and/or backside surface 242 to similarly expose an underlying liner material layer 720 or glass 210 while retaining organic seed material layer 325 within openings 320. In still other embodiments, organic seed material layer 325 is retained over frontside surface 241 and/or backside surface 242.

Returning to FIG. 5, methods 501 continue at block 135 where an inorganic seed material is formed over front and/or back surfaces of a package substrate workpiece. For embodiments where there is no seed material cladding surfaces of a substrate core, the organic seed material formed at block 130 (FIG. 5) may be supplemented with inorganic seed material through the practice of any of the methods or techniques described above for block 135. In the example illustrated in FIG. 10, substrate core 601 further includes inorganic seed material layer 225 in direct contact with glass 210. Alternatively, where organic seed material 325 is retained on surfaces 241, 242, inorganic seed material layer 225 may be in direct contact with organic seed material 325. For either embodiment, inorganic seed material layer 225 may have any of the chemical compositions described above, with one example being predominantly Cu.

As shown in FIG. 10, inorganic seed material layer 225 may be selectively formed over surfaces 241, 242, for example with a non-conformal (directional) deposition process, such as PVD. Parameters of the PVD process, such as power and pressure may be controlled to limit the accumulation of inorganic seed material layer 225 within openings 320. For example, a thickness of inorganic seed material layer 225 may decrease from some nominal thickness normal to frontside surface 241 to null along sidewall 321 beyond a threshold aspect ratio of opening 320. In some exemplary embodiments, inorganic seed material layer 225 is absent from sidewall 321 at a distance of no more than 750 nm from frontside surface 241. In the absence of inorganic seed material layer 225, electrical conductivity of material along sidewall 321 may be advantageously lower than for regions where inorganic seed material layer 225 is present.

With the workpiece covered in a combination of organic and inorganic seed material layers, fabrication of a coaxial magnetic inductor structure may continue with electroplating, for example through one or more plating masks. Returning to FIG. 5, methods 501 continue with forming a masked electroplating of magnetic metal at block 550 followed by masked electroplating of non-magnetic fill metal at block 555. The electroplating process practiced at block 550 may be according to any technique known to be suitable for the magnetic metal. The electroplating process practiced at block 555 may similarly be according to any technique known to be suitable for the fill metal to form a coaxial structure comprising a nonmagnetic metal surrounded by an annulus of magnetic metal.

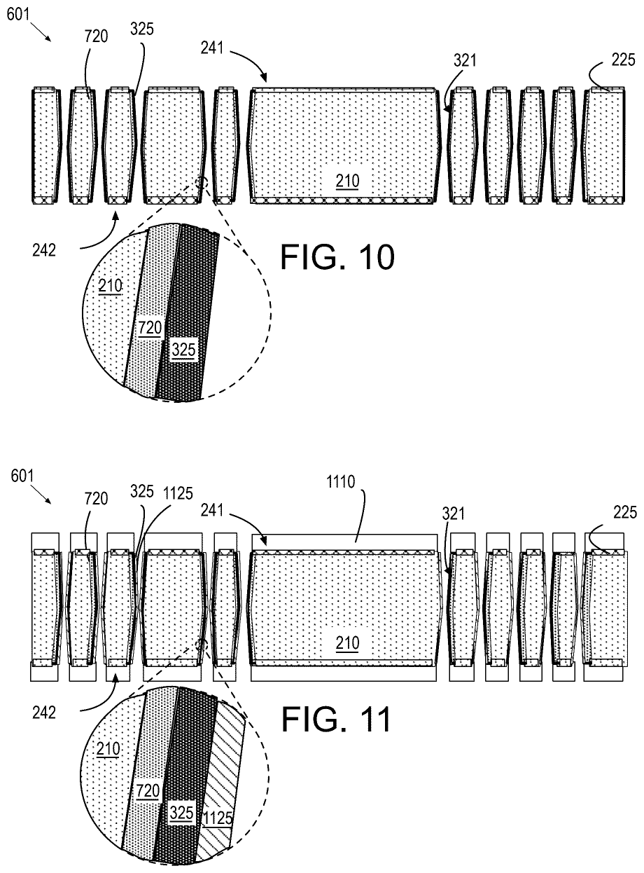

In the example further illustrated in FIG. 11, substrate core 601 includes a plating mask 1110 over frontside glass surface 241 and over backside glass surface 242. Openings in plating mask 1110 encompass openings 320. A magnetic metal 1125 has been plated upon unmasked portions of organic seed material layer 325, as well as unmasked portions of inorganic material layer 225. Hence, within openings 320, magnetic metal 1125 forms a liner over organic seed material layer 325. One or more openings 320 that are not to include magnetic metal 1125 may be protected by a portion of plating mask 1110.

Magnetic metal 1125 may be of any composition known to be compatible with electroplating. Magnetic metal 1125 may advantageously have high magnetic permeability, for example ranging between 5 and 20. Suitable metals include an alloy comprising any of iron, nickel, cobalt, platinum, palladium, manganese, molybdenum, copper, vanadium, indium, aluminum, barium, strontium, and/or zinc. In some exemplary embodiments, magnetic metal 1125 is a ferrite-cobalt (Fe—Co) alloy, which can be readily electroplated. Within an opening 320, magnetic metal 1125 is advantageously a continuous film and has a layer thickness perpendicular from sidewall 321 that may range from 100-500 nm, for example.

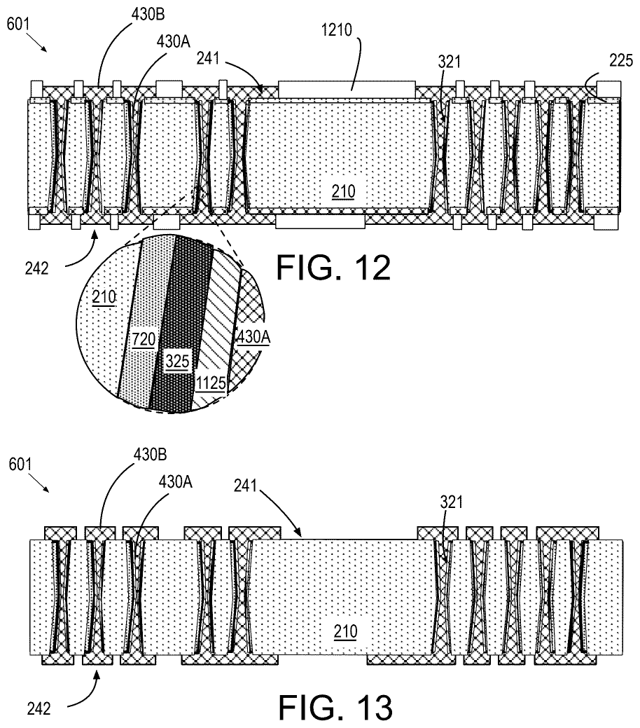

As further illustrated in FIG. 12, plating mask 1110 has been removed from substrate core 601 and replaced with another plating mask 1210 that defines larger openings over frontside surface 241 and backside surface 242, which also encompass openings 320 through glass 210. In the illustrated examples, fill metal 430 may be characterized as a fill metal portion 430A, or axial filament embedded within glass 210 and a fill metal portion 430B over the frontside and backside surfaces of glass 210. As shown in the expanded view of FIG. 12, fill metal portion 430A is in direct contact with magnetic material layer 1125. In contrast, fill metal portion 430B is in direct contact with inorganic seed material layer 225 in regions a non-zero distance beyond an outer edge of magnetic material layer 1125 (e.g., beyond sidewall 321). For any TGV structures that did not receive magnetic metal 1125, fill metal portion 430A may be in direct contact with organic seed material layer 325.

Fill metal portions 430A/430B may be of any metal composition known to be suitable as a conductor embedded within a surrounding magnetic core metal. The fill metal may have any of the compositions previously described elsewhere herein. For example, the fill metal may be predominantly Cu (e.g., substantially pure Cu). For embodiments where inorganic seed material layer 225 and fill metal portions 430A/430B are of substantially the same composition (e.g., both predominantly Cu), an interface between the two may be evident in TEM images revealing inorganic seed material layer 225 to have different microstructure than fill metal portion 430B. For example, seed material layer 225 may have smaller grain sizes (e.g., 5-20 nm grain diameters) than fill metal portion 430B (e.g., >25 nm grain diameters).

After electroplating, all plating mask material and underlying seed material may be removed from the workpiece. In the example illustrated in FIG. 13, plating mask 1210 has been removed and inorganic seed material layer 225 removed, for example with a wet chemical etch. Coaxial inductor structures comprising fill metal portion 430A surrounded by magnetic metal 1125 remain embedded within TGVs extending through glass 210. Organic seed material layer 325 is retained as permanent feature of the coaxial inductor structures. For advantageous embodiments where organic seed material layer 325 has a relatively low electrical conductivity, the coaxial inductor structures may display lower parasitics (e.g., associated with eddy currents) during device operation. Hence, organic seed material layer 325 may enable electrolytic formation of coaxial inductor structures displaying superior performance than those formed with a conventional (inorganic) seed material. Furthermore, coaxial inductor structures may display improved stability because stress may be better accommodated by organic seed material layer 325.

Returning to FIG. 5, methods 501 continue with electrical routing structure build-up at block 560, which electrically couples with the TGVs formed in the substrate core. The routing structure build-up may occur over one or more surfaces of the glass prior to assembly with one or more IC die. The electrical routing structure may be electrically coupled to the coaxial inductor structures and may, for example, comprise one or more levels of metallization features embedded within any suitable dielectric material. The electrical routing structure may interconnect one or more IC die to each other and/or couple one or more of IC die to various types of TGVs (e.g., magnetic and/or non-magnetic). Before or after the formation of the routing structure(s), a workpiece may be affixed to a handle or carrier having any suitable composition and of any suitable thickness, as embodiments herein are not limited in this respect.

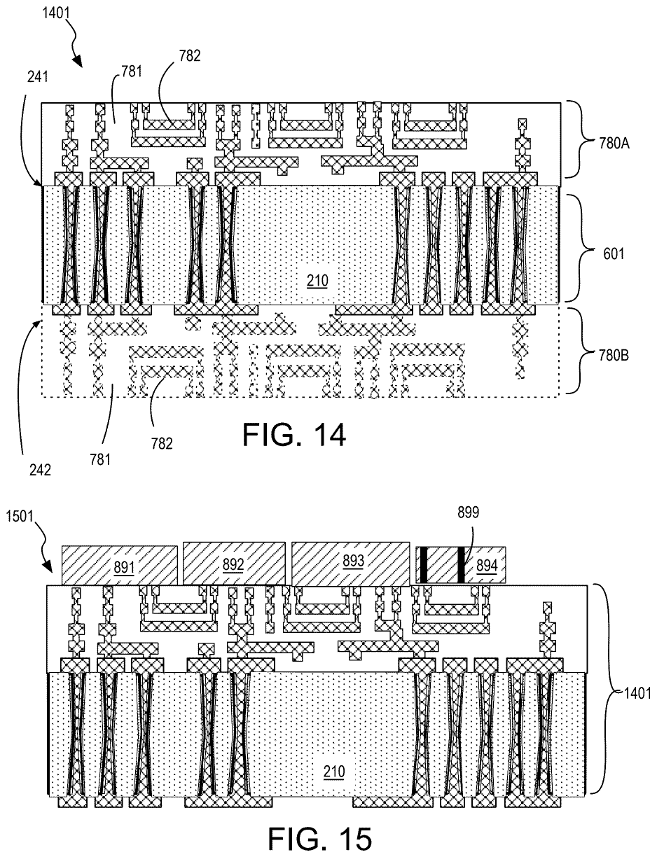

In FIG. 14, package structure 1401 includes a routing structure 780A that has been built-up over surface 241. Another routing structure 780B may be similarly built-up over surface 242. Routing structure 780B is illustrated in dashed line to emphasize double-sided build up is optional. Routing structure 780A(780B) comprises one or more levels of RDL metallization features 782 embedded within one or more layers of dielectric material 781. RDL metallization features 782 may comprise one or more metals, with one example being predominantly copper. At least some of RDL metallization features 782 are to electrically bridge together two or more IC dies, preferably with the finest metallization line: space feature pitch that can be directly patterned (e.g., <3 μm lines and spaces) for the flatness of glass 210. Routing structure 780 may comprises metallization features 782 that are to interconnect multiple IC dies to coaxial inductor structures (or other TGV structures) of substrate core 601. In some examples where the inductor structures include an organic seed material layer, such an organics seed material layers is absent from metallization features 782.

Depending on the embodiment, dielectric material 781 may be any of a molding compound, a spin-on material, or dry film laminate material, for example. Dielectric material 781 may be introduced wet/uncured into a cast and then dried/cured. Alternatively, dielectric material 781 may be introduced as a semi-cured dry film that is fully cured following its application over glass 210. The composition of dielectric material 781 may vary with implementation. In some advantageous embodiments, dielectric material 781 is an organic dielectric, such as, an epoxy resin, phenolic-glass, or a resinous film such as the GX-series films commercially available from Ajinomoto Fine-Techno Co., Inc. (ABF). Dielectric material 781 may comprise epoxy resins (e.g., an acrylate of novolac such as epoxy phenol novolacs (EPN) or epoxy cresol novolacs (ECN)). In some specific examples, dielectric material 781 is a bisphenol-A epoxy resin, for example including epichlorohydrin. In other examples, dielectric material 781 includes aliphatic epoxy resin.

Returning to FIG. 5, methods 101 may continue at block 570 where at least one IC die is optionally assembled to the workpiece and, more particularly, to the electrical routing structure. Each IC die assembled at block 570 may comprise any electrical circuitry, with one example being logic circuitry comprising logic gates. IC die assembled at block 570 may also comprise any photonic circuitry suitable for the detection, emission, or processing (e.g., filtering, multiplexing and demultiplexing) of optical signals.

In the example illustrated in FIG. 15, IC die 891-894 are assembled to interconnect interfaces within a top metallization level of routing structure 780A as the first die of a co-packaged multi-die IC device package structure 1501. IC die 891-894 may be directly bonded to routing structure 780A. Alternatively, IC die 891-894 may be electrically coupled through intervening electrical interconnects (not depicted), which may comprise solder of any suitable composition, for example. In the example illustrated, IC die 891-893 are each flip-chip attached with integrated circuitry within each die being proximal to front-side surface 241. IC die 894 however comprises through die vias 899 with integrated circuity being distal from package substrate surface 241.

Each of IC die 891-894 may be a fully functional ASIC, or may be a chiplet or tile that has more limited functionality supplementing the function of one or more other IC dies that are to be part of the same multi-die device. A chiplet or tile may, for example, be any of a wireless radio circuit, microprocessor core, electronic memory circuit, floating point gate array (FPGA), power management and/or power supply circuit, or include a MEMS device. In some examples, one or more of IC die 891-894 include one or more banks of active repeater circuitry to improve multi-die interconnects (e.g., network-on-chip architectures). In other examples, one or more of IC die 891-894 includes clock generator circuitry or temperature sensing circuitry. In other examples, one or more of IC die 891-894 include logic circuitry that, along with other IC die 891-894 implement multi-chiplet aggregated logic circuitry (e.g., mesh network-on-chip architectures). In some specific examples, at least one of IC die 891-894 includes microprocessor core circuitry, for example comprising one or more shift registers.

IC die 891-894 advantageously comprise field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of less than 30 nm. Additionally, or in the alternative, IC die 891-894 may include active devices other than FETs. For example, IC die 891-894 may include electronic memory structures, such as magnetic tunnel junctions (MTJs), capacitors, or the like.

IC die 891-894 may comprise one or more IC die metallization levels embedded within an insulator. While the IC die metallization features may have any composition(s) of sufficient electrical conductivity, in exemplary embodiments, the IC die metallization features are predominantly copper (Cu). In other examples, the metallization features are predominantly other than Cu, such as, but not limited to predominantly Ru, or predominantly W. An uppermost one of the metallization features within IC die 891-894 may have a feature pitch ranging from 100 nm to several microns, for example.

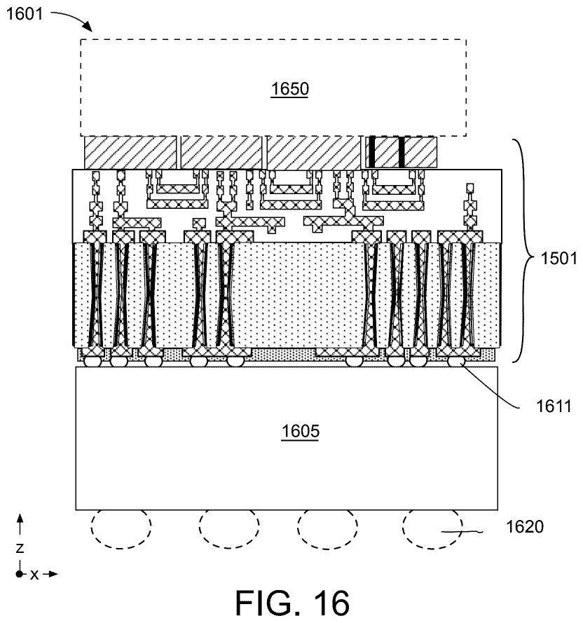

Returning to FIG. 5, methods 501 may end at output 580 where an assembled device package structure may be optionally further attached to a suitable host component. Similar to die attach block 570, output 580 is demarked by dashed line as an option that may instead be performed downstream of methods 501. FIG. 16 illustrates an exemplary system 1601 including one device package structure 1501 attached to a host component 1605 with interconnects 1611, in accordance with some embodiments. In exemplary embodiments, interconnects 1611 are solder (e.g., SAC) microbumps although other interconnect features are also possible. In some embodiments, host component 1605 is predominantly silicon. Host component 1605 may also comprise one or more alternative materials known to be suitable as interposers or package substrates (e.g., an epoxy preform, cored or coreless copper-clad laminate board, FR4, etc.). Host component 1605 may also include a printed circuit board (PCB). Host component 1605 may include one or more metallized redistribution levels (not depicted) embedded within a dielectric material. Host component 1605 may also include one or more IC die embedded therein.

Host component 1605 may include interconnects 1620 illustrated in dashed line. Each of interconnects 1620 may comprise any solder (ball, bump, etc.) suitable for a given host board architecture (e.g., surface mount FR4, etc.). Also illustrated in dashed line, one or more heat spreaders and/or heat sinks 1650 may be further coupled to device package structure 1501, which may be advantageous, for example, where IC dies 891-894 comprise one or more CPU cores or other circuitry of similar power density. Any package dielectric, such as a mold material, may surround sidewalls of IC dies 891-894.

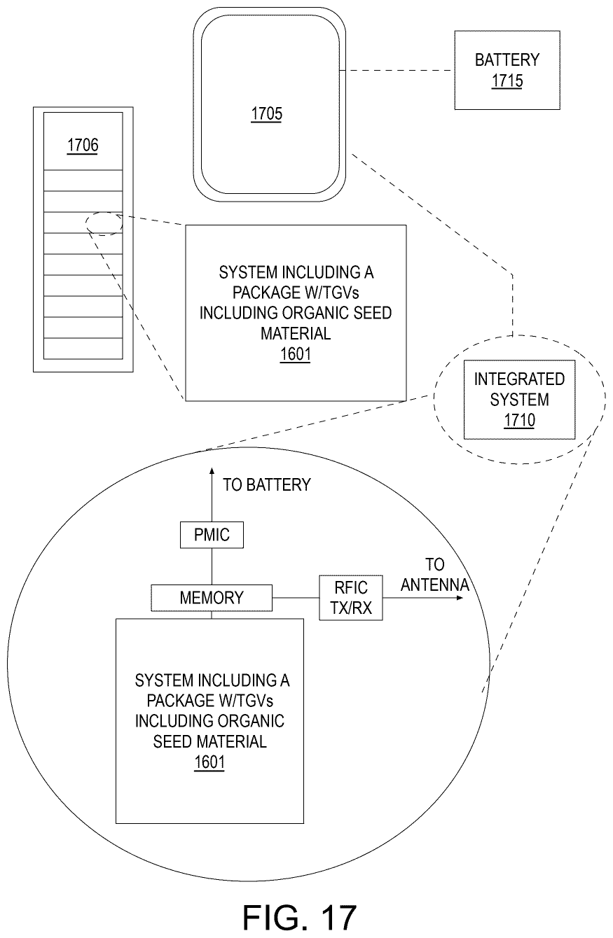

FIG. 17 illustrates a mobile computing platform 1705 and a data server machine 1706 employing an IC device package with TGVs including an organic seed material layer, for example as described elsewhere herein coaxial inductor structures. Server machine 1706 may be any commercial server, for example including any number of high-performance computing platforms disposed within a rack and networked together for electronic data processing, which in the exemplary embodiment includes system 1601, for example as described elsewhere herein. The mobile computing platform 1705 may be any portable device configured for each of electronic data display, electronic data processing, wireless electronic data transmission, or the like. For example, the mobile computing platform 1705 may be any of a tablet, a smart phone, laptop computer, etc., and may include a display screen (e.g., a capacitive, inductive, resistive, or optical touchscreen), an integrated system 1710, and a battery 1715.

As further illustrated in FIG. 17, system 1601 may be coupled to one or more of a power management integrated circuit (PMIC) or RF (wireless) integrated circuit (RFIC) including a wideband RF (wireless) transmitter and/or receiver. A PMIC may perform battery power regulation, DC-to-DC conversion, etc., and so has an input coupled to battery 1715 and with an output providing a current supply to other functional modules. As further illustrated, in the exemplary embodiment, an RFIC has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

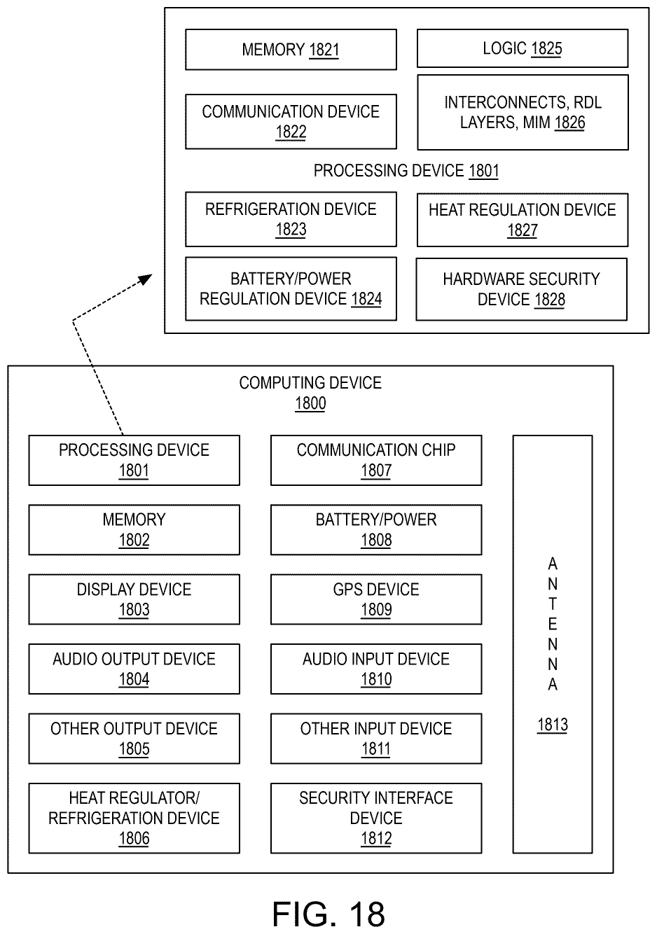

FIG. 18 is a block diagram of a cryogenically cooled computing device 1800 in accordance with some embodiments. For example, one or more components of computing device 1800 may include any of the devices or structures discussed elsewhere herein. A number of components are illustrated in FIG. 18 as included in computing device 1800, but any one or more of these components may be omitted or duplicated, as suitable for the application. In some embodiments, some or all of the components included in computing device 1800 may be attached to one or more printed circuit boards (e.g., a motherboard). In some embodiments, various ones of these components may be fabricated onto a single system-on-a-chip (SoC) die. Additionally, in various embodiments, computing device 1800 may not include one or more of the components illustrated in FIG. 18, but computing device 1800 may include interface circuitry for coupling to the one or more components. For example, computing device 1800 may not include a display device 1803, but may include display device interface circuitry (e.g., a connector and driver circuitry) to which display device 1803 may be coupled.

Computing device 1800 may include a processing device 1801 (e.g., one or more processing devices). As used herein, the term processing device or processor indicates a device that processes electronic data from registers and/or memory to transform that electronic data into other electronic data that may be stored in registers and/or memory. Processing device 1801 may include a memory 1821, a communication device 1822, a refrigeration/active cooling device 1823, a battery/power regulation device 1824, logic 1825, interconnects 1826, a heat regulation device 1827, and a hardware security device 1828.

Processing device 1801 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1801 may include a memory 1802, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1821 includes memory that shares a die with processing device 1801. This memory may be used as cache memory and may include embedded dynamic random-access memory (eDRAM) or spin transfer torque magnetic random-access memory (STT-M RAM).

Computing device 1800 may include a heat regulation/refrigeration device 1806. Heat regulation/refrigeration device 1806 may maintain processing device 1801 (and/or other components of computing device 1800) at a predetermined low temperature during operation. This predetermined low temperature may be any temperature discussed elsewhere herein.

In some embodiments, computing device 1800 may include a communication chip 1807 (e.g., one or more communication chips). For example, the communication chip 1807 may be configured for managing wireless communications for the transfer of data to and from computing device 1800. The term “wireless” and its derivatives may be used to describe circuits, devices, systems, methods, techniques, communications channels, etc., that may communicate data through the use of modulated electromagnetic radiation through a nonsolid medium.

Communication chip 1807 may implement any wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). Communication chip 1807 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1807 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1807 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Computing device 1800 may include an antenna 1813 to facilitate wireless communications and/or to receive other wireless communications (such as AM or FM radio transmissions).

Computing device 1800 may include battery/power circuitry 1808. Battery/power circuitry 1808 may include one or more energy storage devices (e.g., batteries or capacitors) and/or circuitry for coupling components of computing device 1800 to an energy source separate from computing device 1800 (e.g., AC line power).

Computing device 1800 may include a display device 1803 (or corresponding interface circuitry, as discussed above). Display device 1803 may include any visual indicators, such as a heads-up display, a computer monitor, a projector, a touchscreen display, a liquid crystal display (LCD), a light-emitting diode display, or a flat panel display, for example.

Computing device 1800 may include an audio output device 1804 (or corresponding interface circuitry, as discussed above). Audio output device 1804 may include any device that generates an audible indicator, such as speakers, headsets, or earbuds, for example.

Computing device 1800 may include an audio input device 1810 (or corresponding interface circuitry, as discussed above). Audio input device 1810 may include any device that generates a signal representative of a sound, such as microphones, microphone arrays, or digital instruments (e.g., instruments having a musical instrument digital interface (MIDI) output).

Computing device 1800 may include a global positioning system (GPS) device 1809 (or corresponding interface circuitry, as discussed above). GPS device 1809 may be in communication with a satellite-based system and may receive a location of computing device 1800, as known in the art.

Computing device 1800 may include another output device 1805 (or corresponding interface circuitry, as discussed above). Examples include an audio codec, a video codec, a printer, a wired or wireless transmitter for providing information to other devices, or an additional storage device.

Computing device 1800 may include another input device 1811 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1800 may include a security interface device 1812. Security interface device 1812 may include any device that provides security measures for computing device 1800 such as intrusion detection, biometric validation, security encode or decode, managing access lists, malware detection, or spyware detection.

Computing device 1800, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the disclosure is not limited to the embodiments so described but can be practiced with modification and alteration without departing from the scope of the appended claims. For example, the above embodiments may include specific combinations of features as further provided below.

In first embodiments, an apparatus comprises a substrate comprising glass, the glass having a thickness between a first side surface and a second side surface. The apparatus comprises an opening extending through the thickness of the glass and one or more metals within the opening. At least one of the metals is Cu. The apparatus comprises an electrically conductive material layer within the opening, the electrically conductive material layer between the metals and a sidewall of the glass and the electrically conductive material layer comprises carbon and sulfur.

In second embodiments, for any of the first embodiments the electrically conductive material layer is absent from at least one of the first side surface or the second side surface.

In third embodiments, for any of the second embodiments at least one of the one or more metals extends over the first side surface or the second sides surface a non-zero distance beyond a perimeter of the opening.

In fourth embodiments, for any of the first through third embodiments the metals comprise a layer of magnetic alloy in direct contact with the electrically conductive material layer, and a fill metal surrounded by the layer of magnetic alloy. The fill metal comprises predominantly Cu and is physically separated from the electrically conductive material layer by the layer of magnetic alloy.

In fifth embodiments, for any of the fourth embodiments the electrically conductive c material layer is absent from at least one of the first side surface or the second side surface, and the fill metal extends over the first side surface or the second sides surface a non-zero distance beyond an outer edge of the layer of magnetic alloy.

In sixth embodiments, for any of the fourth through fifth embodiments the magnetic alloy comprises Co and Fe.

In seventh embodiments, for any of the first through sixth embodiments the electrically conductive material layer has a layer thickness of at least 100 nm.

In eighth embodiments for any of the seventh embodiments the electrically conductive material layer has a layer thickness of 0.5-5 μm.

In ninth embodiments, for any of the seventh through eighth embodiments the electrically conductive material layer has an electrical conductivity of at least 100 S/cm.

In tenth embodiments, for any of the ninth embodiments the electrically conductive material layer comprises poly(3,4-ethylenedioxythiophene) and poly(styrenesulfonate).

In eleventh embodiments, for any of the first through tenth embodiments the apparatus further comprises a liner within the opening and between the electrically conductive material layer and the sidewall of the glass. The liner comprises an inorganic material layer.

In twelfth embodiments, for any of the eleventh embodiments the inorganic material layer comprises nitrogen at least one of a copper, titanium, silicon, or oxygen.

In thirteenth embodiments, a system comprises a plurality of integrated circuit (IC) die electrically coupled to first metallization features on a first side of a substrate comprising glass. The system comprises a through hole extending through a thickness of the glass between a first side surface and a second side surface of the glass. The system comprises a coaxial metal inductor structure within the through hole. The coaxial metal inductor structure comprises a filament of a metal comprising Cu and extending through the thickness of the glass and an annular layer of magnetic metal alloy cladding the filament. The apparatus comprises a polymer layer lining the through hole between the magnetic metal alloy and the glass.

In fourteenth embodiments, for any of the thirteenth embodiments the polymer layer is in contact with the magnetic metal alloy, the polymer layer has a thickness of at least 200 nm, and the polymer layer is absent from the first side surface and the second side surface.

In fifteenth embodiments, for any of the fourteenth embodiments the polymer layer comprises poly(3,4-ethylenedioxythiophene) and poly(styrenesulfonate).

In sixteenth embodiments, for any of the fourteenth through fifteenth embodiments the system further comprises an electrical routing structure on the first side of the glass, and the routing structure comprises the first metallization features and a dielectric material. The coaxial metal inductor structure extends from the routing structure to a second side of the glass. The routing structure electrically couples the coaxial metal inductor structure to at least one of the IC die.

In seventeenth embodiments, a method comprises receiving a workpiece comprising glass, forming holes through a thickness of the glass, depositing a polymer seed layer over a sidewall of the holes, and electrolytically plating a metallization within the holes by conducting an electrical current through the polymer seed layer.

In eighteenth embodiments, for any of the seventeenth embodiments electrolytically plating the metallization comprises plating a magnetic metal layer within the holes and in contact with the polymer seed layer, and plating a non-magnetic metal within the holes and in contact with the magnetic metal layer.

In nineteenth embodiments, for any of the eighteenth embodiments depositing the organic seed layer comprises coating the workpiece with a fluid precursor, and curing the precursor into the polymer seed layer and having an electrical conductivity of at least 100 S/cm.

In twentieth embodiments, for any of the nineteenth embodiments the method further comprises depositing an inorganic seed layer comprising a metal on a surface of the glass, and the inorganic seed layer is electrically coupled with the polymer seed layer. Electrolytically plating a metallization within the holes comprises conducting the electrical current through the inorganic seed layer and the polymer seed layer.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An apparatus, comprising:
a substrate comprising glass, the glass having a thickness between a first side surface and a second side surface;
an opening extending through the thickness of the glass;
one or more metals within the opening, wherein at least one of the metals is Cu; and
an electrically conductive material layer within the opening, the electrically conductive material layer between the metals and a sidewall of the glass, wherein the electrically conductive material layer comprises carbon and sulfur.

2. The apparatus of claim 1, wherein the electrically conductive material layer is absent from at least one of the first side surface or the second side surface.

3. The apparatus of claim 2, wherein at least one of the one or more metals extends over the first side surface or the second sides surface a non-zero distance beyond a perimeter of the opening.

4. The apparatus of claim 1, wherein the metals comprise:
a layer of magnetic alloy in direct contact with the electrically conductive material layer; and
a fill metal surrounded by the layer of magnetic alloy, the fill metal comprising predominantly Cu and physically separated from the electrically conductive material layer by the layer of magnetic alloy.

5. The apparatus of claim 4, wherein:
the electrically conductive material layer is absent from at least one of the first side surface or the second side surface; and
the fill metal extends over the first side surface or the second sides surface a non-zero distance beyond an outer edge of the layer of magnetic alloy.

6. The apparatus of claim 4, wherein the magnetic alloy comprises Co and Fe.

7. The apparatus of claim 1, wherein the electrically conductive material layer has a layer thickness of at least 100 nm.

8. The apparatus of claim 7, wherein the electrically conductive material layer has a layer thickness of 0.5-5 μm.

9. The apparatus of claim 7, wherein the electrically conductive material layer has an electrical conductivity of at least 100 S/cm.

10. The apparatus of claim 9, wherein the electrically conductive material layer comprises poly(3,4-ethylenedioxythiophene) and poly(styrenesulfonate).

11. The apparatus of claim 1, further comprising a liner within the opening and between the electrically conductive material layer and the sidewall of the glass, wherein the liner comprises an inorganic material layer.

12. The apparatus of claim 11, wherein the inorganic material layer comprises nitrogen at least one of a copper, titanium, silicon, or oxygen.

13. A system, comprising:
a plurality of integrated circuit (IC) die electrically coupled to first metallization features on a first side of a substrate comprising glass;
a through hole extending through a thickness of the glass between a first side surface and a second side surface of the glass;
a coaxial metal inductor structure within the through hole, wherein the coaxial metal inductor structure comprises:
a filament of a metal comprising Cu and extending through the thickness of the glass; and
an annular layer of magnetic metal alloy cladding the filament; and
a polymer layer lining the through hole between the magnetic metal alloy and the glass,
wherein the polymer layer is primarily carbon and further comprises sulfur.

14. The system of claim 13, wherein:
the polymer layer is in contact with the magnetic metal alloy;
the polymer layer has a thickness of at least 200 nm; and
the polymer layer is absent from the first side surface and the second side surface.

15. The system of claim 14, wherein the polymer layer comprises poly(3,4-ethylenedioxythiophene) and poly(styrenesulfonate).

16. The system of claim 15, further comprising an electrical routing structure on the first side of the glass, the routing structure comprising the first metallization features and an dielectric material, and wherein the coaxial metal inductor structure extends from the routing structure to a second side of the glass, and wherein the routing structure electrically couples the coaxial metal inductor structure to at least one of the IC die.

17. A method comprising:
receiving a workpiece comprising glass;
forming holes through a thickness of the glass;
depositing a polymer seed layer over a sidewall of the holes, wherein the polymer seed layer comprises sulfur; and
electrolytically plating a metallization within the holes by conducting an electrical current through the polymer seed layer.

18. The method of claim 17, wherein electrolytically plating the metallization comprises:
plating a magnetic metal layer within the holes and in contact with the polymer seed layer; and
plating a non-magnetic metal within the holes and in contact with the magnetic metal layer.

19. The method of claim 18, wherein depositing the polymer seed layer comprises:
coating the workpiece with a fluid precursor; and
curing the precursor into the polymer seed layer that has an electrical conductivity of at least 100 S/cm.

20. The method of claim 19, wherein the method further comprises depositing an inorganic
seed layer comprising a metal on a surface of the glass, the inorganic seed layer electrically coupled with the polymer seed layer; and
wherein electrolytically plating a metallization within the holes comprises conducting the electrical current through the inorganic seed layer and the polymer seed layer.
